(19) United States
(12) Patent Application Publication
(10) Pub. No.: US 2014/0062967 A1
(43) Pub. Date: Mar. 6, 2014

(54) STYLUS AND CAPACITIVE PRESSURE SENSING ELEMENT EMPLOYED THEREIN

(71) Applicants: FAN-LIN LU, Shenzhen City (CN); PING-HONG WU, Shenzhen City (CN); ZU-PEI HE, Shenzhen City (CN); RUEY-SHYANG YOU, Tu-Cheng (TW); CHUN-WEI PAN, Tu-Cheng (TW)

(72) Inventors: FAN-LIN LU, Shenzhen City (CN); PING-HONG WU, Shenzhen City (CN); ZU-PEI HE, Shenzhen City (CN); RUEY-SHYANG YOU, Tu-Cheng (TW); CHUN-WEI PAN, Tu-Cheng (TW)

(21) Appl. No.: 13/654,627

(22) Filed: Oct. 18, 2012

(30) Foreign Application Priority Data
Aug. 31, 2012 (CN) 2012103178257

(51) Int. Cl. H03K 17/975; G06F 3/033

(52) U.S. Cl. 345/179; 200/600

(57) ABSTRACT

A capacitive pressure sensing element includes a main body, a power supply with a positive electrode and a negative electrode connected to a first electrode and a second electrode mounted on the main body, a first sheet metal electrically connected to the first electrode, a second sheet metal, and a spring element connected between the second electrode and the second sheet metal. When the spring element is uncompressed, the second sheet metal is misaligned relative to the first sheet metal. When the spring element is compressed, the second sheet metal is move towards the first end to a position with a reduced misalignment degree relative to the first sheet metal, thereby the portion of the first sheet metal squarely opposing the second sheet metal is increased to generate an inductive capacitance between the first sheet metal and the second sheet metal. A related stylus is also provided.

### BACKGROUND

1. Technical Field

The present disclosure relates to pressure sensing technology and, particularly, to a stylus and a capacitive pressure sensing element employed therein.

2. Description of the Related Art

Touch screens are common in electronic devices, and such touch input devices may include a touch panel and a stylus for operating the touch panel. The stylus may include a pressure sensing element which is commonly a sensing resistor. However, the sensing resistor is easily and drastically affected by temperature changes and easily unstuck when being used for a long time.

### BRIEF DESCRIPTION OF THE DRAWING

The components in the drawings are not necessarily drawn to scale, the emphasis instead being placed upon clearly illustrating the principles of the disclosure. Moreover, in the drawing, like reference numerals designate corresponding parts throughout the several views.

FIG. 1 is a schematic view of a capacitive pressure sensing element, according to an exemplary embodiment.

FIG. 2 shows the capacitive pressure sensing element of FIG. 1 in a state of use.

FIG. 3 is a diagram of an electronic device employing the capacitive pressure sensing element of FIG. 1.

### DETAILED DESCRIPTION

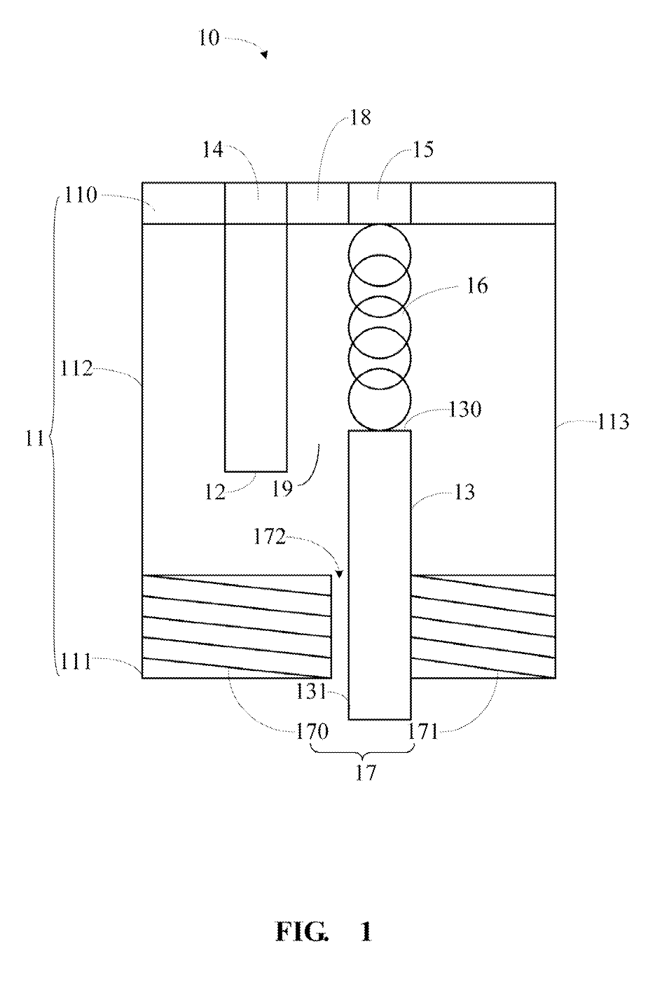

Referring to FIG. 1, a capacitive pressure sensing element 10 includes a main body 11, a first sheet metal 12, a second sheet metal 13, a first electrode 14, a second electrode 15, an spring element 16, a spring 17, and a power supply 18 received in the main body 11. The first electrode 14 and the second electrode 15 are disposed on a first end of 110 of the main body 11, and are respectively connected to a positive electrode and a negative electrode of the power supply 18. In the embodiment, the spring element 16 is a coil spring. The first sheet metal 12 is received in the main body 11 and electrically connected to the first electrode 14, and a first end of the spring element 16 is connected to the second electrode 15 and is in close proximity to the first sheet metal 12. The second sheet metal 13 includes a fixed end 130 and a free end 131. A second end of the spring element 16 is electrically connected to the fixed end 130. A space 19 is defined between the first sheet metal 12 and the spring element 16. In the embodiment, the length of the space 19 along the direction from the first end 110 to a second end 111 of the main body 11 opposite to the first end is substantially equal to the length of the first sheet metal 12 in the same direction. The space 19 is full of conducting medium. When the spring element 16 is elastically deformable between a first state where the spring element is uncompressed, in the embodiment, the second sheet metal 13 is misaligned relative to the first sheet metal 12 by a maximum misalignment degree, in an alternative embodiment, only a portion of the first sheet metal 12 squarely oppose the second sheet metal 13. The main body 11 further includes a first sidewall 112 and a second sidewall 113 opposite to the first sidewall 112. The spring 17 includes a first sub-spring 170 and a second sub-spring 171, respectively connected to the first sidewall 112 and the second sidewall 113. A gap 172 for receiving the second sheet metal 13 is defined between the first sub-spring 170 and the second sub-spring 171. When the free end 131 of the second sheet metal 13 is pressed, the second sheet metal 13 is urged to move up in the gap 172 towards the first end 110.

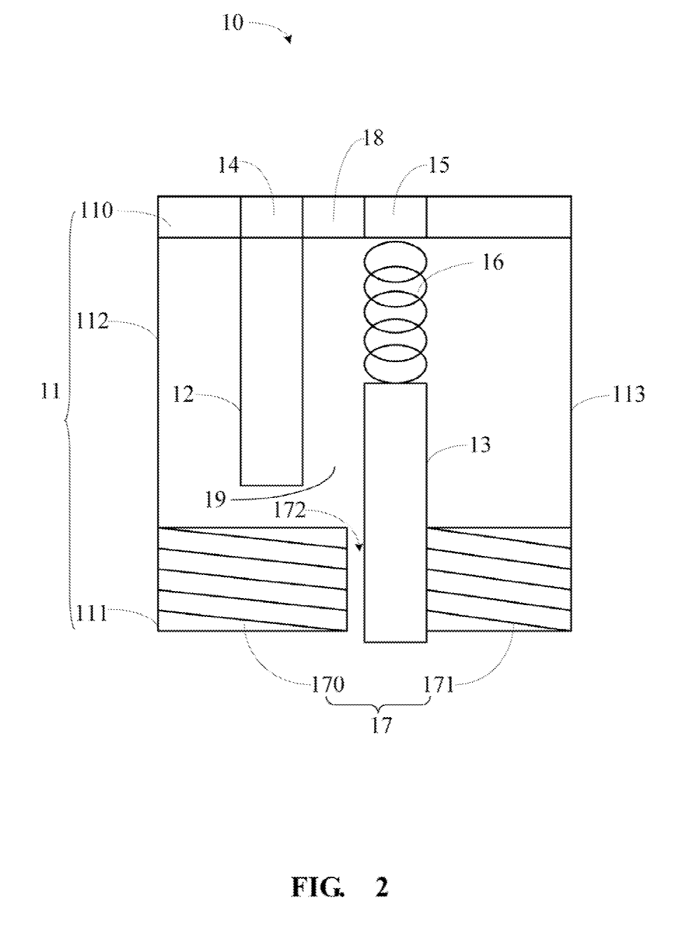

Referring to FIG. 2, in detail, when the free end 131 is pressed, a second state where the spring element 16 is compressed by the second sheet metal 13, and the second sheet metal 13 is moved towards the first end to a position with a reduced misalignment degree relative to the first sheet metal 12. When the second sheet metal 13 moves up towards full opposition against the first sheet metal 12, the portion of the first sheet metal 12 squarely opposing the second sheet metal 13 is increased. An inductive capacitance is generated between the first sheet metal 12 and the second sheet metal 13. The conducting medium of the space 18 is configured for increasing the inductive capacitance. The inductive capacitance proportionally increases as the area of the first sheet metal 12 directly opposing the second sheet metal 13 increases. When the free end 131 is pressed up so as to be totally received in the gap 172, any object which presses up the free end 131 makes contact with the spring 17. The object presses the first sub-spring 171 and the second sub-spring 172 further to urge the free end 131 to move further up towards the first end 110, which results in the portion of the first sheet metal 12 directly opposing the second sheet metal 13 being further increased. When any pressure on the free end 131 is released, the spring element 16 and the spring 17 rebound to their uncompressed states, which makes the second sheet metal 13 return to its initial position, that is, the area of the first sheet metal 12 in direct opposition to the second sheet metal 13 decreases until finally the inductive capacitance disappears.

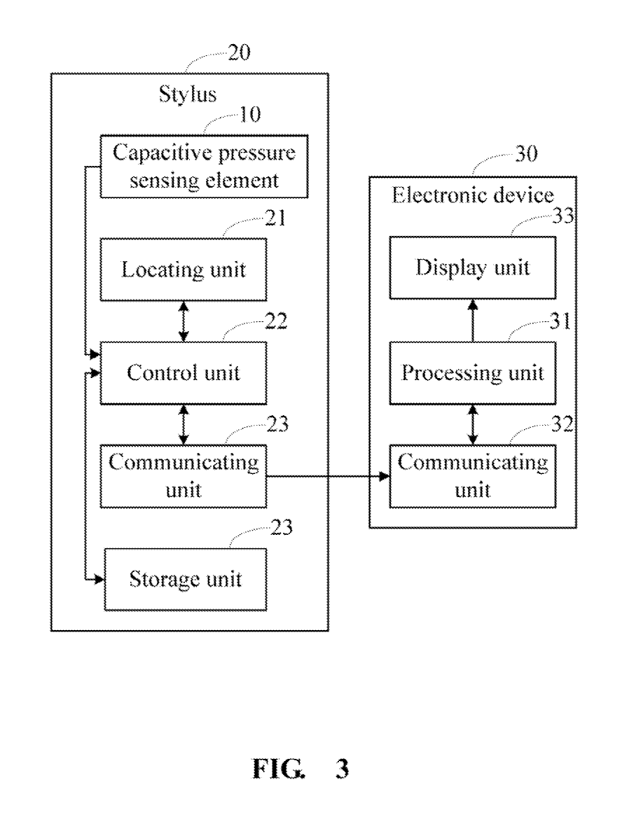

Referring to FIG. 3, the stylus 20 includes the capacitive pressure sensing element 10, a location unit 21, a control unit 22, a communicating unit 23, and a storage unit 24. The storage unit 24 stores a coordinate system (not shown) of a touch screen (not shown) of a touch screen device 30. The coordinate system stored in the storage unit 24 can be updated to match another electronic device. The touch screen device 30 includes a processing unit 31, a communicating unit 32, and a display unit 33.

When the stylus 20 presses the screen of the touch screen device 30, namely, the second sheet metal 13 is pressed by the screen, the element 10 generates an inductive capacitance. The control unit 22 detects the inductive capacitance generated by the element 10, and allows the location unit 21 to determine the pressed position. In the embodiment, the location unit 21 is a gyroscope, when the stylus 20 is pressed, the location unit 21 is configured for determining the coordinate and a displacement direction of the stylus 20. The control unit 22 further obtains the coordinate system stored in the stored unit 24, and determines the relevant coordinates in the coordinate system, and transmits the determined coordinates to the electronic device 30 via the communicating unit 23.

The electronic device 30 receives the coordinates transmitted by the stylus 20 via the communicating unit 32, the processing unit 31 determines the position of the stylus 20 on the screen according to the received coordinates, and the display unit 33 displays the position under the control of the processing unit 31. Thus, if the stylus 20 moves across the screen of the electronic device 30 continuously in a specific track, the display unit 33 of the electronic device 30 displays the track.

The present disclosure may be embodied in other forms without departing from the spirit thereof. Thus, the present examples and embodiments are to be considered in all respects as illustrative and not restrictive, and the disclosure is not to be limited to the details given herein.

What is claimed is:

1. A capacitive pressure sensing element comprising:
a main body including a first end and an opposite second end;
a power supply received in the main body, the power supply including a positive electrode and a negative electrode;
a first electrode mounted on the first end of the main body, and connected to the positive electrode of the power supply;
a second electrode mounted on the first end of the main body, and connected to the negative electrode of the power supply;
a first sheet metal received in the main body and electrically connected to the first electrode,
a second sheet metal received in the main body; and
a spring element connected between the second electrode and the second sheet metal, the spring element being elastically deformable between a first state where the spring element is uncompressed, the second sheet metal is misaligned relative to the first sheet metal by a maximum misalignment degree; and a second state where the spring element is compressed, and the second sheet metal is moved towards the first end to a position with a reduced misalignment degree relative to the first sheet metal, thereby the portion of the first sheet metal squarely opposing the second sheet metal is increased to generate an inductive capacitance between the first sheet metal and the second sheet metal.

2. The capacitive pressure sensing element as claimed in claim 1, further comprising a space defined between the first sheet metal and the spring element, the space being full of conducting medium configured for increasing the inducting capacitance generating between the first sheet metal and the second sheet metal.

3. The capacitive pressure sensing element as claimed in claim 2, wherein the space and the first sheet metal are oriented in the same direction and have a substantially same length in said direction.

4. The capacitive pressure sensing element as claimed in claim 1, further comprising a first sub-spring and a second sub-spring respectively connected to a first sidewall of the main body and a second sidewall of the main body opposite to the first sidewall, a gap for receiving the second sheet metal is defined between the first sub-spring and the second sub-spring.

5. The capacitive pressure sensing element as claimed in claim 1, wherein when the spring element is in the first state, only a portion of the first sheet metal squarely oppose the second sheet metal.

6. A stylus for a touch screen device, comprising:
a capacitive pressure sensing element including
a main body including a first end and an opposite second end;
a power supply received in the main body, the power supply including a positive electrode and a negative electrode;
a first electrode mounted on the first end of the main body, and connected to a the positive electrode of the power supply;
a second electrode mounted on the first end of the main body, and connected to the negative electrode of the power supply;
a first sheet metal received in the main body and electrically connected to the first electrode,
a second sheet metal received in the main body; and
a spring element connected between the second electrode and the second sheet metal, the spring element being elastically deformable between a first state where the spring element is uncompressed, the second sheet metal misaligned relative to the first sheet metal by a maximum misalignment degree; and a second state where the spring element is compressed, and the second sheet metal is moved towards the first end to a position with a reduced misalignment degree relative to the first sheet metal, thereby the portion of the first sheet metal squarely opposing the second sheet metal is increased to generate an inductive capacitance between the first sheet metal and the second sheet metal;
a storage unit configured for storing a coordinate system of a touch screen of a touch screen device;
a location unit configured for determining the current position of the stylus on the screen in response to the inductive capacitance generated by the capacitive pressure sensing element;
a control unit configured for determining the coordinates of stylus in the coordinate system according to the current position determined by the location unit; and
a communicating unit configured for transmitting the coordinates of the position of the stylus determined by the control unit to the touch screen device.

7. The stylus as claimed in claim 6, further comprising a space arranged between the first sheet metal and the spring element, the space being full of conducting medium configured for increasing the inducting capacitance generating between the first sheet metal and the second sheet metal.

8. The stylus as claimed in claim 7, wherein the space and the first sheet metal are oriented in the same direction and have a substantially same length in said direction.

9. The stylus as claimed in claim 7, further comprising a first sub-spring and a second sub-spring respectively connected to a first sidewall of the main body and a second sidewall of the main body opposite to the first sidewall, a gap is defined between the first sub-spring and the second sub-spring for receiving the second sheet metal.

10. The stylus as claimed in claim 9, wherein when the second sheet metal is pressed towards the first end to a position with a minimum misalignment degree relative to the first sheet metal, the first sub-spring and the second sub-spring are pressed by the touch screen.

11. The stylus as claimed in claim 6, wherein when the spring element is in the first state, only a portion of the first sheet metal squarely opposes the second sheet metal.

12. The stylus as claimed in claim 6, wherein the location unit is a gyroscope configured for determining a displacement direction of the stylus.

13. The stylus as claimed in claim 12, wherein when the stylus does not touch the touch screen, the spring element is in the first state, and there is no inductive capacitance generated between the first and second sheet metal.
